(19) United States
(12) Patent Application Publication
(10) Pub. No.: US 2009/0102503 A1
(43) Pub. Date: Apr. 23, 2009

(54) SEMICONDUCTOR DEVICE, SEMICONDUCTOR CHIP, INTERCHIP INTERCONNECT TEST METHOD, AND INTERCHIP INTERCONNECT SWITCHING METHOD

(75) Inventor: Hideaki Saito, Tokyo (JP)

Correspondence Address: YOUNG & THOMPSON, 209 Madison Street, Suite 500, ALEXANDRIA, VA, 22314, US

(73) Assignee: NEC CORPORATION, TOKYO (JP)

(21) Appl. No.: 12/064,639

(22) PCT Filed: Aug. 22, 2006
(86) PCT No.: PCT/JP2006/316410

§ 371 Date: Feb. 25, 2008

(30) Foreign Application Priority Data
Aug. 23, 2005 (JP) 2005-241039

(51) Int. Cl. G01R 31/26

(52) U.S. Cl. 324/765

(57) ABSTRACT

A semiconductor device is provided with a first wiring (110) between chips, for electrically connecting a first semiconductor chip with a second semiconductor chip; an auxiliary second wiring (120) between chips; a test signal generating circuit (4) for transmitting a test signal from the first semiconductor chip to the second semiconductor chip through the first wiring; a judging circuit (8), which outputs a first control signal in the case of receiving the test signal through the first wiring, and outputs a second control signal, i.e., the inversion signal of the first control signal, in the case of not receiving the test signal; and switching circuits (5, 6), which set the first wiring as a channel when the first control signal is inputted from the judging circuit, and set the second wiring when the second control signal is inputted

### TECHNICAL FIELD

The present invention relates to a semiconductor chip, a semiconductor device having a plurality of semiconductor chips, an interchip interconnect test method, and an interchip interconnect switching method.

### BACKGROUND ART

With the miniaturization of semiconductor integrated circuits, integration density is increasing and advances are being made for increased CPU performance and increased memory capacity. Nevertheless, there is a limit to the miniaturization of semiconductors, and new technology is now demanded to achieve greater integration density. As one example of such a technology, three-dimensional semiconductors are being proposed in which semiconductor chips are laminated.

A means for stacking semiconductor chips to achieve large-scale integrated circuits without changing the chip area is disclosed in JP-A-H04-196263 (hereinbelow referred to as Patent Document 1), wherein memory circuits are integrated in separate chips that are stacked on a semiconductor integrated circuit unit.

In addition, a multilayered memory construction in which a memory cell array is realized in multiple layers and with greater capacity is described in JP-A-2002-026283 (hereinbelow referred to as Patent Document 2).

Realizing a semiconductor chip as a multilayered construction necessitates interchip interconnects in addition to the conventional wiring within the chip plane. One example of such interchip interconnects is the through-type interconnect that passes from the obverse side to the reverse side of the semiconductor substrate of the chip to achieve an increase in wiring density.

In a report by K. Takahashi et al. in Japanese Journal of Applied Physics (40, 3032 (2001)), through-type interconnects are formed for interchip interconnects by reducing the thickness of a silicon substrate of a semiconductor chip to 50 μm, forming holes 10 μm square that pass from the obverse side of the substrate to the reverse side, and then filling these holes with metal. By means of these through-type interconnects, interchip interconnects can be arranged two-dimensionally within the chip surface, and several hundred interchip interconnects can be formed.

However, when several hundred interchip interconnects are formed by through-type interconnects, a through-type interconnect defective rate of just 1% results in a near-zero yield of satisfactory stacked semiconductor devices. Accordingly, extra interchip interconnects must be used to provide redundancy. As one redundancy remedial method for interchip interconnects, defective interchip interconnects having disconnects or short circuits are specified in a conductivity test of the interchip interconnects as a testing step in the process of device fabrication. Based on the test results, the address of a defective site is programmed using fuses equipped in chips for each stacked semiconductor device. Then, when the device is used, the route of the defective interchip interconnect is switched to the route of the reserve interchip interconnect based on the programmed address. However, this method necessitates a test step and fuse programming step for each stacked semiconductor device and is therefore costly.

When the number of interchip interconnects in a device is 100 or more, specifying one defective interconnect requires an address code of seven or more bits, and when there is a plurality of defective interchip interconnects, this amount of address code is required for each of the number of defective interconnects. The area of a fuse takes up several hundred μm² per bit, and the amount of chip surface occupied by fuses becomes significant as the number of fuses increases.

In addition, when a step of testing interchip interconnects is carried out before chip stacking, faults that occur due to defects in conductivity when connecting interchip interconnects at the time of stacking chips cannot be remedied. On the other hand, when the test step is carried out after chip stacking, fuses that have been packaged on the chip are buried in the stacked chips, thereby preventing the use of laser fuses that are cut by laser irradiation from the obverse surface of the chip. Electrical fuses can be programmed even when buried, but such fuses are only beginning to see practical use and their utility is therefore limited.

A technique for using incorporated circuits to test and remedy interchip interconnect defects after the completion of a semiconductor device that is distinct from the above-described methods in which the test process and remedy of interchip interconnect defects are implemented during the process of chip fabrication is disclosed in JP-A-2003-309183 (hereinbelow referred to as Patent Document 3). In this method, data for test signals for carrying out conductivity tests of interchip interconnects are all transmitted to the sending side of the interchip interconnects. After these test signal data have been passed through each individual interchip interconnect, all of the sending side and receiving side data are transmitted to a match determination circuit provided at a specific site within the chip to compare the test signal data on the receiving side with the original test signal data. In the transmission of these data, flip-flops are connected and the data are scanned. Alternatively, a form is also shown in which a match determination circuit is provided for each interchip interconnect, but in such a case, a test signal that has been accepted after passage through an interchip interconnect is returned to the sending side by again using the interchip interconnect following which the match determination is carried out. In addition, components such as test data storage elements, test result storage elements, and connection re-arrangement circuits are required on both ends of all interchip interconnects.

### DISCLOSURE OF INVENTION

In a stacked semiconductor device in which chips are stacked, testing and remedying of interchip interconnects during use of the device is effective, but when considering the implementation of these processes at the time of starting up the device, the series of operations is preferably carried out in a short time period. When the device is in operation, temperature increases, and conductivity of interchip interconnects that was normal at the time of start-up may become defective. For example, when the chip temperature rises to 80°, the difference in the thermal expansion coefficients between a chip and a chip interconnect raises the possibility for breakage of connections between the chip and chip interconnect. In response to the occurrence of such defects during operation, a method is sought in which the testing and remedying is carried out in an extremely short time interval of several cycles of the operation frequency during operation of the device rather than at the time of start-up of the device.

In the method described in Patent Document 3, the scan of test data necessitates a time interval of clock cycles equal to the number of interchip interconnects, and even when a match determination circuit and test signals are provided for each interchip interconnect, time is necessary for returning receiving-side test data to their origin, carrying out testing for each of low and high to test the transmission of low and high signals, and further, collecting test results and switching wiring, and the implementation of these processes during operation of the device is therefore problematic.

In the case of through-type interconnects used for interchip interconnects in a stacked semiconductor device in particular, considering that the number of interchip interconnects rises to several hundred or that the spacing between interchip interconnects is as little as several tens of μm, the circuit scale must be reduced to provide circuits for testing and remedying for each interchip interconnect.

The present invention was achieved to solve the drawbacks inherent to the above-described related art and has as its object the provision of a semiconductor chip, semiconductor device, interchip interconnect testing method, and interchip interconnect switching method for detecting defects of interchip interconnects, and in accordance with the detection results, switching to normal interchip interconnects.

The semiconductor device of the present invention for achieving the above-described object is of a configuration that includes: a first interchip interconnect for electrically connecting a first semiconductor chip and a second semiconductor chip; a second interchip interconnect for a reserve for the first interchip interconnect; a test signal generation circuit provided on the first semiconductor chip for transmitting test signals by way of the first interchip interconnect to the second semiconductor chip; a determination circuit provided on the second semiconductor chip for supplying a first control signal upon receiving a test signal by way of the first interchip interconnect and for supplying a second control signal that is an inverted signal of the first control signal when a test signal is not received; and a switching circuit provided on the second semiconductor chip for setting the first interchip interconnect as a path for electrically connecting the first semiconductor chip and the second semiconductor chip upon receiving as input the first control signal from the determination circuit and for setting the second interchip interconnect as the path upon receiving as input the second control signal.

According to the present invention, the first interchip interconnect is selected as the interchip path if a test signal from the test signal generation circuit reaches the second semiconductor chip from the first semiconductor chip by way of the first interchip interconnect. On the other hand, if the test signal does not reach the second semiconductor chip, a fault in the first interchip interconnect is determined and the second interchip interconnect that is the reserve interconnect is selected as the path.

In the present invention, an interchip interconnect for electrically connecting a plurality of semiconductor chips is subjected to a determination for checking whether the interchip interconnect is functioning or not, and switching to a normal interchip interconnect is effected according to the results of this determination. If these processes from determination to switching can be effected within several cycles of the operating frequency, resetting to the reserve interchip interconnect can be realized even when the interchip interconnect becomes defective during operation of the semiconductor device.

### BRIEF DESCRIPTION OF THE DRAWINGS

FIG. 1 is a schematic view showing an example of the configuration of the stacked semiconductor device of exemplary embodiment;

FIG. 2 shows an example of interconnects for connecting circuit 100A and circuit 100B shown in FIG. 1;

FIG. 3 is a flow chart showing the procedure of the interchip interconnect switching method;

FIG. 4 shows an example of the configuration of the test determination circuit;

FIG. 5 shows another example of the configuration of the test determination circuit;

FIG. 6 shows signal waveforms when a regular interchip interconnect is normal and when the interchip interconnect is defective;

FIG. 7 is a schematic view showing an example of the configuration in which a plurality of regular interchip interconnects are provided on chip A;

FIG. 8 shows an example of the circuit structure when selection between regular and reserve interchip interconnects is also carried out on chip A;

FIG. 9 is a schematic view of the stacked semiconductor device of working example 1;

FIG. 10 shows an example of the redundancy remedy circuit configuration of chip A and chip B;

FIG. 11 shows the signal waveforms produced by the operation of the configuration shown in FIG. 10;

FIG. 12A is a schematic view showing the configuration of the stacked semiconductor device of working example 2;

FIG. 12B is an enlarged view of the redundancy switching portion of the stacked semiconductor device shown in FIG. 12A; and

FIG. 13 shows an example of the redundancy remedy circuit configuration of chip C and chip D shown in FIG. 12A.

### EXPLANATION OF THE REFERENCE NUMBERS

4 test signal generation circuit
8 test determination circuit
1-3, 5, 6 tristate buffers

### BEST MODE FOR CARRYING OUT THE INVENTION

The semiconductor device of the present invention includes: a circuit for transmitting a test signal to an interchip interconnect; a circuit for determining whether an interchip interconnect is defective or not according to whether a test signal was received or not; and a circuit for switching an interchip interconnect having a fault to a reserve interchip interconnect.

Explanation next regards the semiconductor device of the present exemplary embodiment. The following explanation regards a stacked semiconductor device having a configuration in which a plurality of semiconductor chips are stacked.

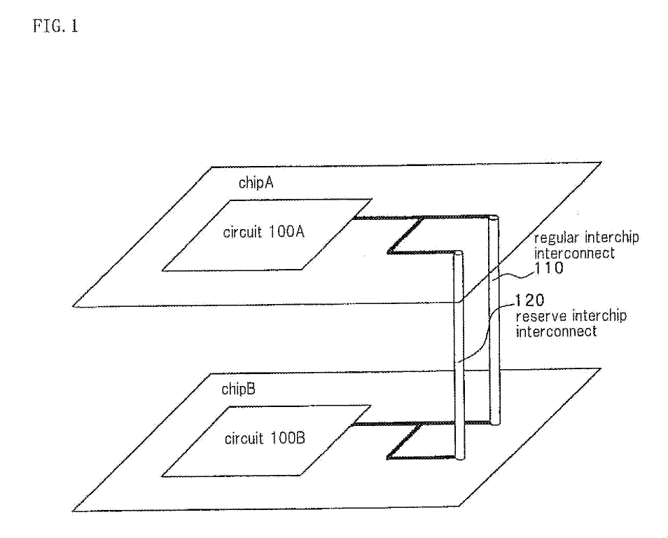

FIG. 1 is a schematic view showing an example of the configuration of the stacked semiconductor device.

As shown in FIG. 1, the stacked semiconductor device is of a configuration in which chip A is stacked on chip B. Circuit 100A is provided on chip A, and circuit 100B is provided on chip B. Interchip interconnects for transmitting signals between the chips are provided between chip A and chip B. The interchip interconnects include regular interchip interconnect 110, and in addition, reserve interchip interconnect 120 that becomes an interconnect in place of regular interchip interconnect 110 when regular interchip interconnect 110 has become defective due to a disconnect or short-circuit. In addition, regular interchip interconnect 110 and reserve interchip interconnect 120 are through-type interconnects and are shown schematically in FIG. 1.

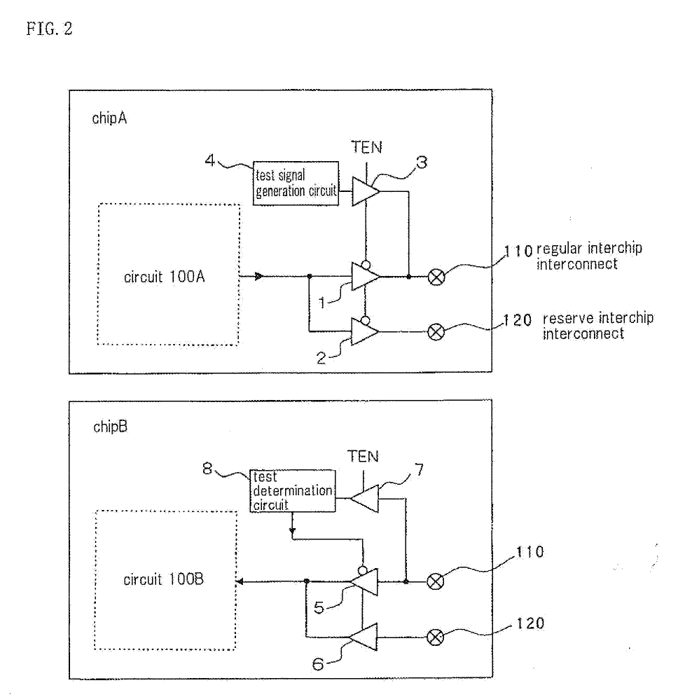

FIG. 2 shows an example of the interconnects for connecting circuit 100A and circuit 100B shown in FIG. 1.

As shown in FIG. 2, tristate buffer 1 is connected in a series in the wiring that joins circuit 100A and regular interchip interconnect 110 on chip A. In addition, the junction point between circuit 100A and tristate buffer 1 is connected by wiring to reserve interchip interconnect 120, and tristate buffer 2 is connected in a series midway in this wiring. Still further, test signal generation circuit 4 is connected to the junction point between tristate buffer 1 and regular interchip interconnect 110. In addition, tristate buffer 3 is connected in a series between this junction point and test signal generation circuit 4.

On chip B, tristate buffer 5 is connected in a series in the wiring that joins circuit 100B and regular interchip interconnect 110. In addition, reserve interchip interconnect 120 is connected by wiring to the junction point between circuit 100B and tristate buffer 5, and tristate buffer 6 is connected in a series midway in this wiring. Still further, test determination circuit 8 is connected to the junction point between tristate buffer 5 and regular interchip interconnect 110. Tristate buffer 7 is connected in a series between this junction point and test determination circuit 8. Test determination circuit 8 and tristate buffer 5 are connected by wiring, and signals supplied from test determination circuit 8 are applied as control signals to tristate buffer 5.

According to the level of control signals received as input, the tristate buffers shown in FIG. 2 either enter an “enable” state that connects the interior (IN) and exterior (OUT), or conversely, enter a high-impedance state. Entering the high-impedance state results in a state that is equivalent to isolation of the interior from the outside. In the case shown in FIG. 2, tristate buffers 1, 2, and 5 having a circle at the control signal input terminal are enabled when the control signals have low-level voltage. Tristate buffer 6 that lacks a circle at the control signal input terminal is enabled when the control signal has high-level voltage.

On chip A, a signal from circuit 100A is sent to both regular interchip interconnect 110 and reserve interchip interconnect 120 if tristate buffers 1 and 2 are enabled. On chip B, either tristate buffer 5 connected to the output of regular interchip interconnect 110 or tristate buffer 6 connected to the output of reserve interchip interconnect 120 is enabled. If there is no problem such as a fault in regular interchip interconnect 110, the control signal from test determination circuit 8 causes tristate buffer 5 on the regular interchip interconnect 110 side to enter the enabled state and regular interchip interconnect 110 is selected as the signal path to circuit 10B. If regular interchip interconnect 110 is defective, the control signal from test determination circuit 8 causes tristate buffer 6 on the reserve interchip interconnect 120 side to enter the enabled state and reserve interchip interconnect 120 is selected as the signal path to circuit 100B. Tristate buffers 5 and 6 serve as a switching circuit for selecting interchip interconnects.

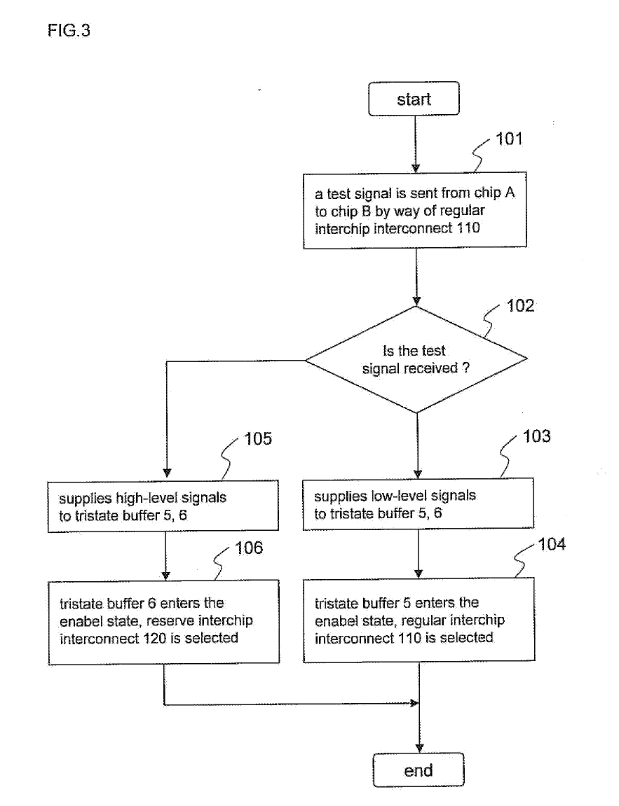

Explanation next regards the operation of the circuit shown in FIG. 2. FIG. 3 is a flow chart showing the procedure of the interchip interconnect switching method. The information “1” corresponds to the high level of the signal level, and information “0” corresponds to low level of the signal level.

At the time of start-up of the stacked semiconductor device, the output from test determination circuit 8 on chip B to tristate buffers 5 and 6 is set to the initial value “1”, whereby reserve interchip interconnect 120 is selected as the interchip interconnect that transmits the signal to circuit 100B in the initial state.

Next, in order to test the interchip interconnect, tristate buffers 1 and 2 on the path of the interchip interconnect from circuit 100A of chip A are switched from the enabled state to high impedance to enable tristate buffer 3 on the path that connects from test signal generation circuit 4 to regular interchip interconnect 110. In this state, the test signal is sent to chip B by way of regular interchip interconnect 110 (Step 101).

Test determination circuit 8 determines whether the test signal from chip A is received or not (Step 102). If regular interchip interconnect 110 is normal, the test signal is transmitted to chip B and sent to test determination circuit 8. Test determination circuit 8, upon receiving the test signal as a control signal, changes its output from the initial value “1” to “0” (Step 103). This value is saved in test determination circuit 8 as the determination result, Upon receiving the information “0” as a control signal from test determination circuit 8, tristate buffer 5 enters the enabled state. On the other hand, the enabled state of tristate buffer 6 is canceled, whereby regular interchip interconnect 110 is selected as the path (Step 104).

In contrast, if regular interchip interconnect 110 is defective in Step 102, the test signal supplied from test signal generation circuit 4 is not sent to test determination circuit 8. In this case, the value saved in test determination circuit 8 as the determination result remains the initial value “1” without change (Step 105), whereby the interchip interconnect that transmits signals to circuit 100B is reserve interchip interconnect 120 that was selected in the initial state (Step 106).

Regular interchip interconnect 110 can be determined to be normal or defective by examining the output signal of test determination circuit 8 that results from the determination result of Step 102. As a result, the process from Step 101 to 103 and Step 105 is equivalent to the procedure of the test method for investigating whether regular interchip interconnect 110 is normal. In addition, the test method and the interconnect switching method shown in FIG. 3 are carried out between two chips at a prescribed timing, and the number of times these tests are carried out is not limited to one time and may be a plurality of times.

If regular interchip interconnect 110 is normal, the determination result of test determination circuit 8 of chip B is “0”. This determination result is applied as input to tristate buffers 5 and 6 in the output portion of the interchip interconnects of chip B as a switch control signal. Tristate buffer 6 on the reserve interchip interconnect 120 side then enters the high-impedance state, tristate buffer 5 on the regular interchip interconnect 110 side enters the enabled state, and the path switches to regular interchip interconnect 110. On the other hand, if regular interchip interconnect 110 is defective, the determination result of test determination circuit 8 remains as “1” without change and reserve interchip interconnect 120 therefore is maintained in the selected state.

Explanation next regards test determination circuit 8.

FIG. 4 shows an example of the configuration of a test determination circuit. As shown in FIG. 4, test determination circuit 8 is of a configuration that includes flip-flop circuit 30 and carries out test determinations of the frequency level of data that are exchanged by the interchip interconnects. A toggle waveform equivalent to data that repeats lows and highs at the operating frequency is taken as the test signal.

The application of a toggle waveform signal that passes through an interchip interconnect to the clock input terminal of flip-flop circuit 30 causes the output timing of the data input value to differ as follows depending on the type of flip-flop circuit 30. When flip-flop circuit 30 is of a type that detects the rising edge of the clock input waveform, flip-flop circuit 30 supplies a data input value when the input test signal transitions from low to high. When flip-flop circuit 30 is of a type that detects the falling edge of the clock input waveform, flip-flop circuit 30 supplies a data input value when the input test signal transitions from high to low. Accordingly, in either case, the data output of flip-flop circuit 30 is first set to “1”, and if the data input is made “0”, the output changes to “0” only when the toggle signal is received as input in the clock terminal.

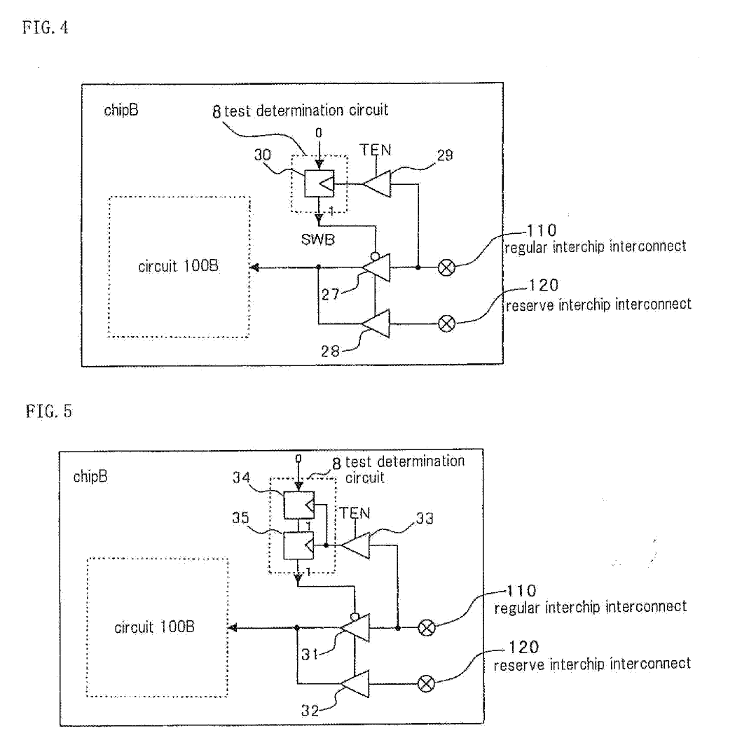

FIG. 5 shows another example of the configuration of the test determination circuit. As shown in FIG. 5, test determination circuit 8 is of a configuration that includes a shift register in which two flip-flop circuits 34 and 35 are connected in a series. In this case, the output changes to “0” only if the toggle waveform to the clock terminal makes two or more transitions from low to high, thus enabling a more reliable determination.

The foregoing operation is next described by signal waveforms.

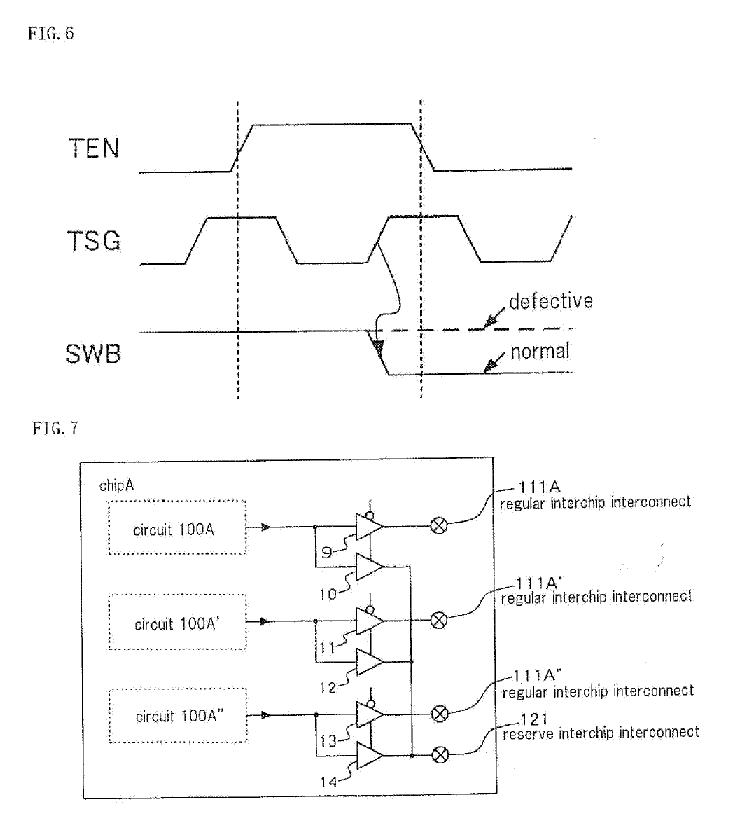

FIG. 6 shows the signal waveforms both when a regular interchip interconnect is normal and when the regular interchip interconnect is defective. In this case, test determination circuit 8 is of a configuration that includes one flip-flop circuit of the type that detects a rising edge.

The test mode is started when tristate buffer 3 of chip A and tristate buffer 7 of chip B shown in FIG. 2 are enabled by control signal TEN. Test signal generation circuit 4 of chip A sends the toggle waveform of test signal TSG to regular interchip interconnect 110. When regular interchip interconnect 110 is normal, test signal TSG is applied as input to the clock input terminal of flip-flop circuit 30 of test determination circuit 8 of chip B shown in FIG. 4. Flip-flop circuit 30 supplies data input value “0” to the output terminal when received test signal TSG transitions from low to high. As shown in FIG. 6, output value SWB becomes the low level shown by the solid line at the time of the rise of test signal TSG.

On the other hand, when regular interchip interconnect 110 becomes defective due to, for example, a disconnection, the clock input terminal of flip-flop circuit 30 remains in a high-impedance state or, in the case of short-circuiting to a fixed voltage such as the ground potential or power supply potential, remains at this voltage without changing. As a result, flip-flop circuit 30 maintains the state of supplying the initial value “1” and does not supply data input value “0” to the output terminal. As shown in FIG. 6, output value SWB maintains the high level shown by the broken line.

By means of this test method, a determination regarding the transmission of a high-level signal and the transmission of a low level signal is possible by detecting only one transition from low to high. In other words, there is no need for comparison of signals of high level on the sending side and high level on the receiving side or low level on the sending side and low level on the receiving side.

Further, as shown in FIG. 4, output value SWB of flip-flop circuit 30 is without alteration the control signal of tristate buffers 27 and 28 that switch regular interchip interconnect 110 and reserve interchip interconnect 120, and the interconnect is therefore switched at the same time as testing.

If the processing from testing to interconnect switching is completed in a minimum of one data interchip input/output cycle, testing and interconnect switching operations can be inserted as appropriate not only at the time of start-up of the device but also during operation. This capability is effective for dealing with defects in interconnects between chips that occur with the rise in chip temperature during operation.

The smallest circuit structure required for the above-described testing and interconnect switching control for one regular interchip interconnect is one flip-flop circuit of the test determination circuit, two tristate buffers, one reserve interchip interconnect, and one tristate buffer on receiving-side chip B, as shown in FIG. 4. On the other hand, a test signal generation circuit is necessary on the sending-side chip A as shown in FIG. 2. However, the test signal is a toggle signal in which a low-level voltage and high-level voltage repeat, and the clock signal used for synchronization of circuit 100A or a frequency-divided clock signal may therefore be used as this test signal, whereby a new circuit such as a test signal generation circuit need not be added. Accordingly, the circuit scale for testing and switching can be kept small even when the number of interchip interconnects is on the order of several hundred.

The testing and automatic switching of redundancy remedying of interchip interconnects is carried out by the configuration of FIG. 2, but signals from circuit 100A flow to both regular and reserve interchip interconnects. Considering the power consumption of charging and discharging of the interconnects, it is advantageous to also select either one of paths on the input side of interchip interconnect.

Explanation next regards a case of redundancy remedy by one reserve interchip interconnect for a plurality of regular interchip interconnects.

FIG. 7 is a schematic view showing an example of a configuration in which a plurality of regular interchip interconnects are provided on chip A.

As shown in FIG. 7, circuit 10A, circuit 100A′, and circuit 100A″ are provided on chip A. Circuit 100A is connected by way of tristate buffer 9 to regular interchip interconnect 111A and by way of tristate buffer 10 to reserve interchip interconnect 121. Circuit 100A′ is connected by way of tristate buffer 11 to regular interchip interconnect 111A″ and by way of tristate buffer 12 to reserve interchip interconnect 121. Circuit 100A″ is connected by way of tristate buffer 13 to regular interchip interconnect 111A′″ and by way of tristate buffer 14 to reserve interchip interconnect 121.

When the redundancy remedy was realized for one regular interchip interconnect by one reserve interchip interconnect as shown in FIG. 2, there was no need to select which of regular interchip interconnect and reserve interchip interconnect on the input side to the interchip interconnect on chip A, but selection was necessary for the output side from an interchip interconnect on chip B. In contrast, when the redundancy remedy is realized by one reserve interchip interconnect for a plurality of regular interchip interconnects, selection of which of the regular interchip interconnects and reserve interchip interconnect as shown in FIG. 7 is also necessary on the input side to the interchip interconnects to distinguish a defective regular interchip interconnect from other normal regular interchip interconnects.

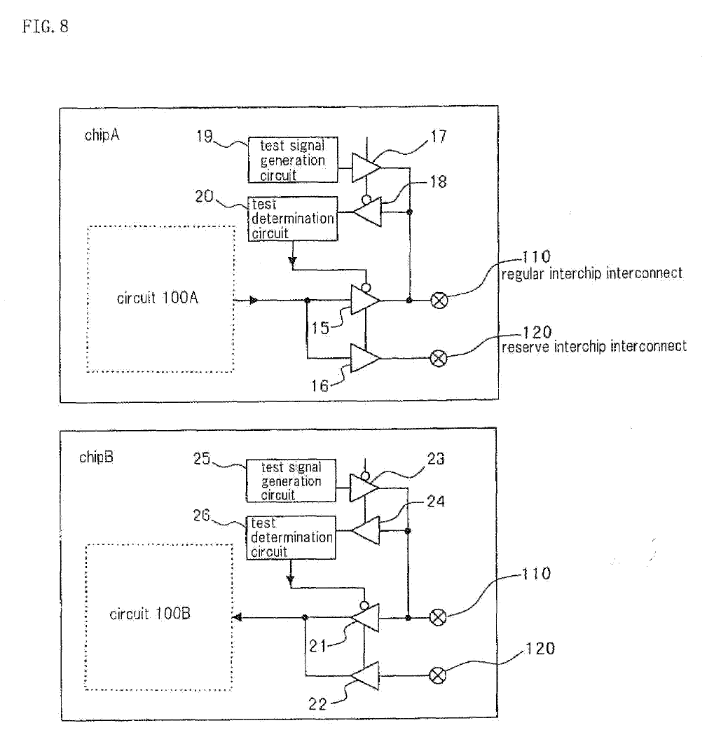

FIG. 8 shows an example of the circuit configuration of chip A and chip B when the selection of regular and reserve interchip interconnects is also carried out on chip A.

As shown in FIG. 8, circuit 100A of chip A is connected to regular interchip interconnect 110 by way of tristate buffer 15 and connected to reserve interchip interconnect 120 by way of tristate buffer 16. Test signal generation circuit 19 is connected by way of tristate buffer 17 to the junction point of the wiring that connects circuit 100A and reserve interchip interconnect 110. In addition, test determination circuit 20 is connected by way of tristate buffer 18 to this same junction point. Tristate buffers 15 and 18 are enabled when the control signal is low level, and tristate buffers 16 and 17 are enabled when the control signal is high level.

Regarding chip B, circuit B is connected by way of tristate buffer 21 to regular interchip interconnect 110 and connected by way of tristate buffer 22 to reserve interchip interconnect 120. Test signal generation circuit 25 is connected by way of tristate buffer 23 to the junction point of the wiring that connects circuit 100B and regular interchip interconnect 110. In addition, test determination circuit 26 is connected by way of tristate buffer 24 to this same junction point. Tristate buffers 21 and 23 are enabled when the control signal is low level, and tristate buffers 22 and 24 are enabled when the control signal is high level.

Explanation next regards the operation of the circuit configuration shown in FIG. 8.

When the stacked semiconductor device is started up, both of the outputs of test determination circuits 20 and 26 on chip A and chip B are set to initial value “1”, whereby tristate buffers 15 and 21 that precede and follow regular interchip interconnect 110 are in a high-impedance state in their initial states. In addition, tristate buffers 16 and 22 that precede and follow reserve interchip interconnect 120 are in the enabled state, whereby circuit 100A and circuit 100B are in a state in which the exchange of signals is carried out not by regular interchip interconnect 110 but by reserve interchip interconnect 120.

Test signal generation circuit 19 of chip A next supplies and sends a test signal to regular interchip interconnect 110. When regular interchip interconnect 110 is normal, the test signal is transmitted to chip B and applied as input to test determination circuit 26. Upon receiving the test signal, test determination circuit 26 changes the determination result that was “1” in the initial state to “0” and saves this value. When the output of test determination circuit 26 becomes “0”, this determination result serves as a switching control signal to enable tristate buffer 21 and set tristate buffer 22 to high impedance, and on chip B, the path with circuit B is switched from reserve interchip interconnect 120 to regular interchip interconnect 110.

When regular interchip interconnect 110 is defective, the test signal supplied from chip A is not sent to test determination circuit 26 of chip B. In this case, the value saved as the determination result in test determination circuit 26 is the initial value “1” without change. As a result, on chip B reserve interchip interconnect 120 is maintained as the path with circuit 10B.

Test signal generation circuit 25 on chip B supplies and sends a test signal to regular interchip interconnect 110. Test determination circuit 20 of chip A now carries out a determination as follows. If regular interchip interconnect 110 is normal, test determination circuit 20 receives the test signal and supplies “0” as output. However, if regular interchip interconnect 110 is defective, test determination circuit 20 does not receive the test signal and supplies the initial value “1” as output without change.

If regular interchip interconnect 110 is normal, tristate buffer 15 is enabled, tristate buffer 16 enters a high-impedance state, and the path with circuit A switches from reserve interchip interconnect 120 to regular interchip interconnect 110 on chip A. If regular interchip interconnect 110 is defective, reserve interchip interconnect 120 is maintained as the path with circuit 100A on chip A.

In this way, testing from the two directions above and below interchip interconnects and the selection of paths by either of regular and reserve interchip interconnects are carried out on both chip A and chip B, the regular interchip interconnect being selected when the regular interchip interconnect is normal and the reserve interchip interconnect being selected when the regular interchip interconnect is defective to implement the redundancy remedy.

The upward and downward bidirectional testing and automatic switching of paths are carried out simultaneously by each of the interchip interconnects even when there is a plurality of interchip interconnects. Even when there are three or more stacked chips, the implementation of the above-described method for each chip allows the testing and automatic switching of paths for redundancy remedying to be carried out simultaneously for the plurality of chips. Accordingly, testing and redundancy remedying of interchip interconnects can be carried out in a short time interval at the time of start-up or during operation of a stacked semiconductor device.

In addition, the transmission timing and transmission period of test signals is made to correspond to the input/output cycles of data that are exchanged between chip A and chip B. If the processes from testing to the interconnect switching is completed within one cycle of data input/output, the testing and interconnect switching operations can be inserted as appropriate not only at the time of start-up of the device, but during operation as well.

In the present invention, interchip interconnects for electrically connecting a plurality of semiconductor chips are subjected to a determination for investigating whether interchip interconnects are normal or defective and to switching to normal interchip interconnects in accordance with the determination results. If the processes from the determination to the switching of interconnects are carried out in several cycles of the operating frequency, resetting to a reserve interchip interconnect can be achieved even when an interchip interconnect becomes defective during the operation of the semiconductor device. Further, compared to a conventional wafer test and remedy method by fuses, the present invention not only reduces the costs of the test process at the time of fabrication but also eliminates the need for fuses.

### WORKING EXAMPLE 1

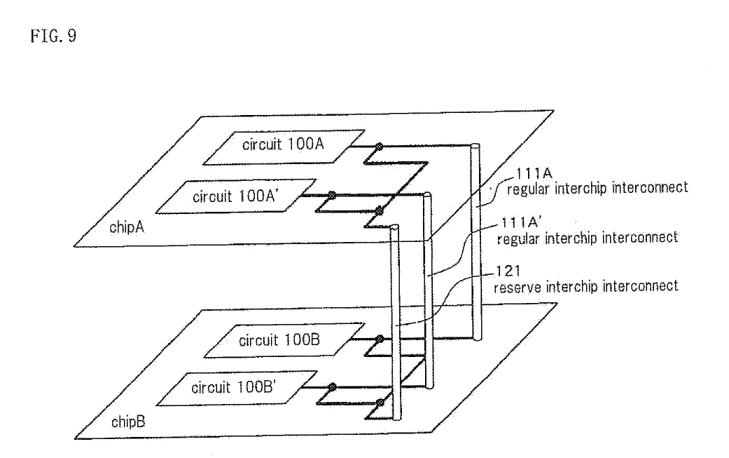

Explanation next regards the configuration of a stacked semiconductor device of the present working example with reference to the accompanying figures. FIG. 9 is a schematic view of a stacked semiconductor device of the present working example.

As shown in FIG. 9, the stacked semiconductor device of the present working example is of a configuration in which chip A is stacked on chip B. Circuit 100A and circuit 100A′ are provided on chip A. Circuit 100B and circuit 100B′ are provided on chip B. Connections between the chips are realized by regular interchip interconnect 111A, regular interchip interconnect 111A′, and reserve interchip interconnect 121.

In the present working example, chip A and chip B are stacked, and two regular interchip interconnects and one reserve interchip interconnect are provided for transmitting signals from chip A to chip B. When an electrical defect such as a disconnect or a short circuit occurs in either of the two regular interchip interconnects, a redundancy remedy is effected by switching the defective interchip interconnect to the transmission path of the reserve interchip interconnect.

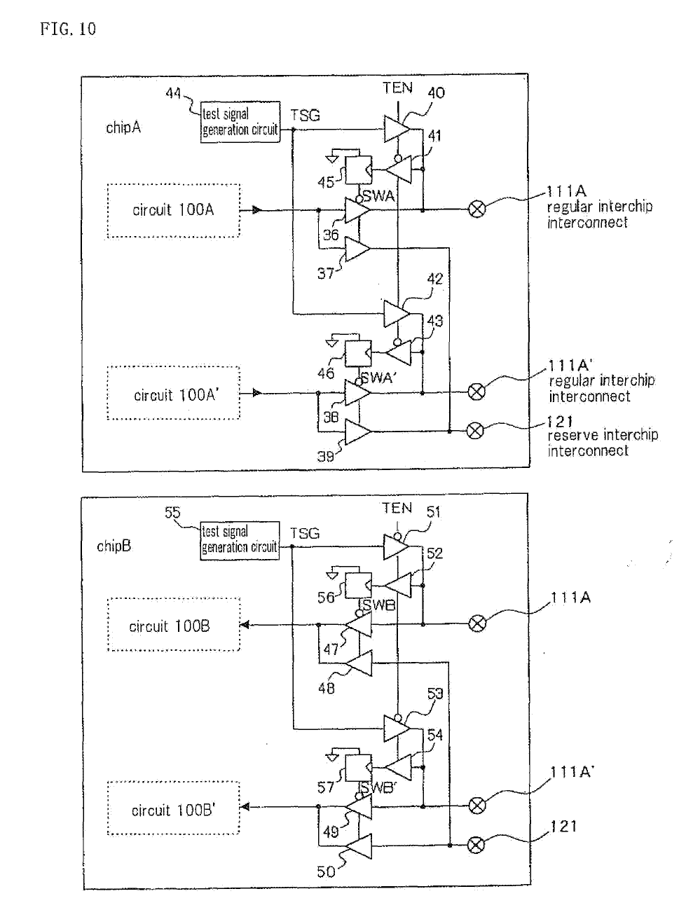

Explanation next regards the redundancy remedy circuit configuration of chip A and chip B shown in FIG. 9. FIG. 10 shows an example of the redundancy remedy circuit configuration of chip A and chip B.

As shown in FIG. 10, tristate buffer 36 for selecting the path from circuit 100A to regular interchip interconnect 111A and tristate buffer 37 for selecting the path from circuit 100A to reserve interchip interconnect 121 are each provided on respective paths on chip A. In addition, tristate buffer 38 for selecting a path from circuit 100A′ to regular interchip interconnect 111A′ and tristate buffer 39 for selecting a path from circuit 100A′ to reserve interchip interconnect 121 are each provided on a respective path.

Test signal generation circuit 44 for sending test signals to chip B and flip-flop circuits 45 and 46 for determining test signals received from chip B are provided on chip A. Test signal generation circuit 44 of chip A is connected by way of tristate buffer 40 to the path to regular interchip interconnect 111A. Test signal generation circuit 44 is further connected by way of tristate buffer 42 to the path to regular interchip interconnect 111A′. Flip-flop circuit 45 is connected by way of tristate buffer 41 to the path from regular interchip interconnect 111A. Flip-flop circuit 46 is connected by way of tristate buffer 43 to the path from regular interchip interconnect 111A′. Control signals applied as input to tristate buffers 40 and 41 select whether test signals from test signal generation circuit 44 are sent to chip B or test signals received from chip B are applied as input to flip-flop circuit 45. Tristate buffers 42 and 43 also function similarly to tristate buffers 40 and 41, respectively.

As shown in FIG. 10, tristate buffer 47 for selecting a path from regular interchip interconnect 111A to circuit 100B and tristate buffer 48 for selecting a path from reserve interchip interconnect 121 to circuit 100B are each provided on a respective path on chip B. Tristate buffer 49 for selecting a path from regular interchip interconnect 111B′ to circuit 100B′ and tristate buffer 50 for selecting a path from reserve interchip interconnect 121 to circuit 100B′ are each provided on a respective path.

Test signal generation circuit 55 for sending test signals to chip A and flip-flop circuits 56 and 57 for determining test signals received from chip A are provided on chip B. Test signal generation circuit 55 on chip B is connected by way of tristate buffer 51 to the path to regular interchip interconnect 111A, and further, is connected by way of tristate buffer 53 to the path to regular interchip interconnect 111A′. Flip-flop circuit 56 is connected by way of tristate buffer 52 to the path from regular interchip interconnect 111A. Flip-flop circuit 57 is connected by way of tristate buffer 54 to the path from regular interchip interconnect 111A′. Control signals applied to tristate buffers 51 and 52 select whether test signals from test signal generation circuit 55 are sent to chip A or test signals received from chip A are applied as input to flip-flop circuit 56. Tristate buffers 53 and 54 function similarly to tristate buffers 51 and 52, respectively.

To give test signals a toggle waveform equivalent to the repetition of high and low of data at the operating frequency, test signal generation circuits 44 and 55, upon receiving clock signals of the operating frequency, frequency-divide and supply these signals.

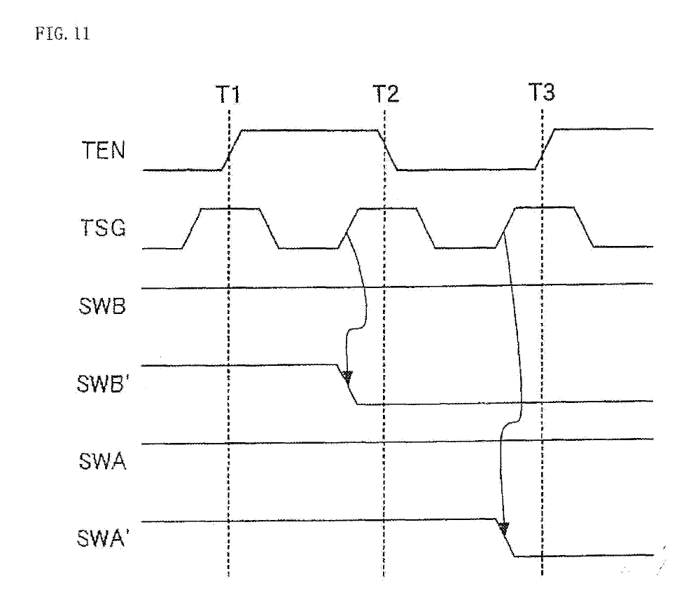

Explanation next regards the operations for the testing and redundancy remedy switching of interchip interconnects that are carried out at the time of start-up of the stacked semiconductor device of the present working example with reference to the example of circuit configuration shown in FIG. 10 and FIG. 11 that shows the signal waveform produced by the operation of the configuration shown in FIG. 10. It is here assumed that regular interchip interconnect 111A is electrically defective and that regular interchip interconnect 111A′ is normal.

First, output is set to the initial value “1” for flip-flop circuits 45, 46, 56, and 57 of the test determination circuits in four locations, whereby the path of reserve interchip interconnect 121 is selected and regular interchip interconnects 111A and 111A′ are not selected.

To test whether regular interchip interconnects 111A and 111A′ are normal or defective, a high-level control signal TEN is applied as input to tristate buffer 40 and tristate buffer 42 and these circuits are placed in an enabled state (broken line T1 in FIG. 11). Test signal generation circuit 44 of chip A generates low and high toggle signal TSG and sends the toggle signal to tristate buffers 40 and 42 as a test signal. Regular interchip interconnect 111A is electrically defective, and the toggle signal that was sent from tristate buffer 40 therefore does not arrive in chip B. Regular interchip interconnect 111A′ is normal, and the toggle signal sent from tristate buffer 42 therefore arrives in chip B.

On chip B, tristate buffers 52 and 54 are placed in enabled states by control signals such that signals from each of regular interchip interconnects 111A and 111A′ are applied as input to the clock input terminals of each of flip-flop circuits 56 and 57 that are test determination circuits. Because regular interchip interconnect 111A is electrically defective, the toggle signal is not applied as input to the clock input terminal of flip-flop circuit 56 that determines this defective state and the output SWB of flip-flop circuit 56 remains as the initial value “1” without change.

On the other hand, because regular interchip interconnect 111A′ is normal, the toggle signal that is the test signal from chip A is applied as input to the clock input terminal of flip-flop circuit 57 that determines this normal state, whereby the output SWB′ of flip-flop circuit 57 transitions from the initial value “1” to the input value “0” (the interval of broken lines T1 and T2 in FIG. 11). Accordingly, the path to circuit 100B remains the path that uses reserve interchip interconnect 121, but the path to circuit 100B′ is switched to the path that uses regular interchip interconnect 111A′. In this way, the paths on chip B are selected. This state of selected paths is maintained until flip-flop circuit 57 is again set to the initial value (initialized) or until the power supply of the stacked semiconductor device is cut off and the power supply to flip-flop circuit 57 is halted.

Test signal generation circuit 55 of chip B next sends a test signal to chip A and the selection of the path on chip A is carried out as follows. On chip B, when tristate buffers 51 and 53 are enabled by low-level control signal TEN, the toggle signal supplied as output from test signal generation circuit 55 is sent to regular interchip interconnect 111A and regular interchip interconnect 111A′ as a test signal.

Regular interchip interconnect 111A is electrically defective, and the toggle signal is therefore not applied as input to the clock input terminal of flip-flop circuit 45 on chip A, and flip-flop circuit 45 maintains the output SWA of initial value “1.” On the other hand, regular interchip interconnect 111A′ is normal, and the toggle signal is therefore applied as input to the clock input terminal of flip-flop circuit 46 on chip A, and flip-flop circuit 46 causes the transition of output SWA′ from initial value “1” to the input value “0” (the interval of broken lines T2 and T3 in FIG. 11). As a result, the path to circuit 100A remains unchanged as the path using reserve interchip interconnect 121, but the path to circuit 100A′ switches to the path that uses regular interchip interconnect 111A′. In this way, the paths on chip A are selected. This state of selected paths is maintained until flip-flop circuit 46 is again set to the initial value or until the power supply to the stacked semiconductor device is cut off.

As described in the foregoing explanation, test determinations and path switching are carried out by the transmission of test signals from chip A to chip B and the transmission of test signals from chip B to chip A, the paths of interchip interconnects being determined on both chip A and chip B. The testing process is completed in the time interval of two cycles of the operating frequency. In addition, the determination interval of test signals is limited by the time interval of the high or low of control signal TEN. Thus, taking as an example a defect in which a interchip interconnect conducts but has extremely high resistance, the waveform of the test signal is extremely blunted by the time it passes through the interchip interconnect, and the interchip interconnect can therefore be determined as defective within the determination interval without completion of the transition of the test signal that is applied as input to the flip-flop.

The testing and path switching of interchip interconnects are carried out by circuits that are incorporated within the stacked semiconductor device, and it is therefore possible to make automatic all of the procedures of starting a test at the time of start-up or during operation of the device, applying a test pattern as input to interchip interconnects, and effecting the redundancy remedy.

Explanation in the present working example regarded a case in which regular interchip interconnect 111A is defective and regular interchip interconnect 111A′ is normal, but when regular interchip interconnect 111A is normal and regular interchip interconnect 111A′ is defective, regular interchip interconnect 111A is selected for the transmission between circuit 100A and circuit 100B and reserve interchip interconnect 121 is selected in the transmission between circuit 100A′ and circuit 100B′. In addition, when both of regular interchip interconnect 111A and regular interchip interconnect 111A′ are normal, these interchip interconnects are selected and reserve interchip interconnect 121 is not selected as a path.

Although the number of regular interchip interconnects in the present working example was two, this number may be increased and determination circuits arranged for each of the interchip interconnects. The number of reserve interchip interconnects may also be increased, but in this case, a function must be added for selecting which reserve interchip interconnect to use when switching for the redundancy remedy.

Although through-type interconnects were adopted for the interchip interconnects in the present working example, the interconnects may also be interconnects that do not penetrate chips such as wire bonding interconnects or integrated circuit in which chip surfaces having circuits are placed in confrontation and input/output signal pads then flip-chip bonded.

Although a configuration was adopted in the present working example in which a plurality of chips are stacked vertically, a configuration may also be adopted in which chips are aligned horizontally. Three or more chips may be aligned horizontally. In this case as well, the same interchip interconnect testing and switching can be carried out. Similar effects can also be realized for a case of two or more semiconductor devices that include chips or for interconnects that link together chips of separate semiconductor devices.

### WORKING EXAMPLE 2

The stacked semiconductor device of the present working example is a device in which five chips are stacked.

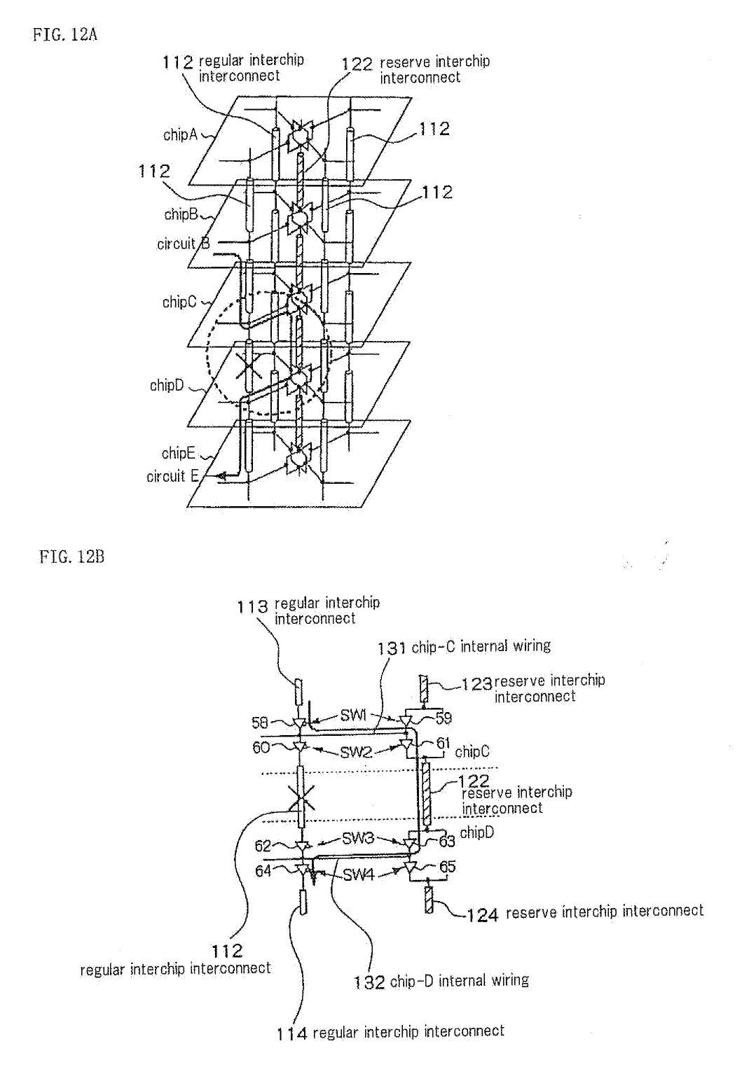

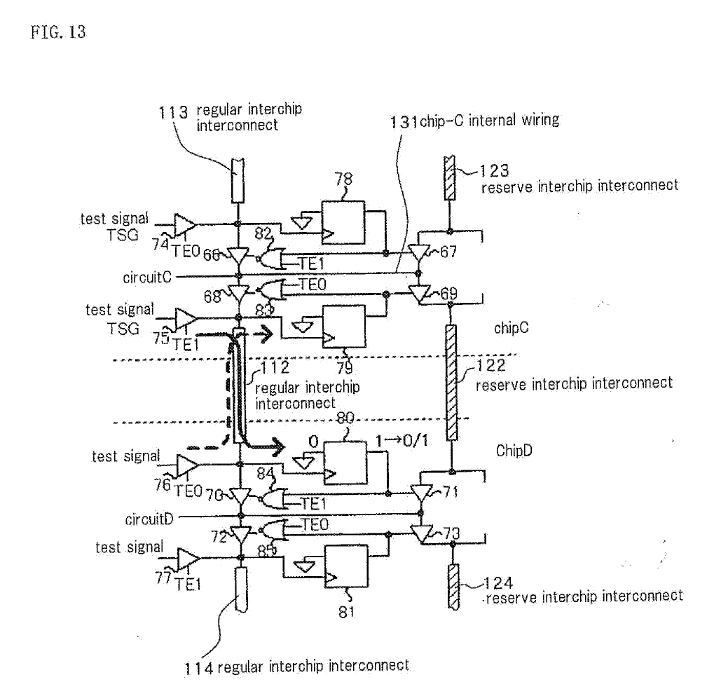

FIG. 12A is a schematic view showing the configuration of a stacked semiconductor device of the present working example. FIG. 12B is an enlargement of a portion of the redundancy switching portion shown by the broken lines in FIG. 12A.

As shown in FIG. 12A, the stacked semiconductor device is of a configuration in which chip E, chip D, chip C, chip B, and chip A are stacked in order from the bottom. One reserve interchip interconnect is provided for four regular interchip interconnects between each of the chips. In FIG. 12A, the reference numbers of regular interchip interconnects 112 and reserve interchip interconnect 122 are shown only for interconnects between chip A and chip B.

FIG. 12B shows the redundancy switching portion of chip C and chip D. Here, only one of the four regular interchip interconnects is taken up for the sake of simplifying the explanation. As shown in FIG. 12B, regular interchip interconnect 112 between chip C and chip D is connected by way of tristate buffers 60 and 58 on chip C to regular interchip interconnect 113 between chip B and chip C, and further, is connected by way of tristate buffers 62 and 64 on chip D to regular interchip interconnect 114 between chip D and chip E.

Reserve interchip interconnect 122 between chip C and chip D is connected by way of tristate buffers 61 and 59 in chip C to reserve interchip interconnect 123 between chip B and chip C, and further, by way of tristate buffers 63 and 65 in chip D to reserve interchip interconnect 124 between chip D and chip E.

On chip C, chip-C internal wiring 131 is provided for connecting the junction point of tristate buffers 60 and 58 and the junction point of tristate buffers 61 and 59. On chip D, chip-D internal wiring 132 is provided for connecting the junction point of tristate buffers 62 and 64 to the junction point of tristate buffers 63 and 65.

Tristate buffers 58, 60, 62, and 64 are enabled when the control signal is low level. Tristate buffers 59, 61, 63, and 65 are enabled when the control signal is high level. The control signal applied as input to tristate buffers 58 and 59 is SW1, and the control signal applied as input to tristate buffers 60 and 61 is SW2. The control signal applied as input to tristate buffers 62 and 63 is SW3, and the control signal applied as input to tristate buffers 64 and 65 is SW4.

When SW2 and SW3 are made low level in the above-described configuration, regular interchip interconnect 112 is selected as the path between chip C and chip D. On the other hand, when SW2 and SW3 are made high level, reserve interchip interconnect 122 is selected as the path between chip C and chip D. In this way, regular interchip interconnects and reserve interchip interconnect can be selected between each of the chips. In addition, if the regular interchip interconnect between chip C and chip B and the regular interchip interconnect between chip D and chip E are normal, SW1 and SW4 become low level.

FIG. 12B shows an example in which one regular interchip interconnect between chip C and chip D (regular interchip interconnect 112) is defective and the signals of SW2 and SW3 are made high level to switch to reserve interchip interconnect 122.

Explanation next regards a configuration for enabling the determination of whether an interchip interconnect is normal or not and path switching in the stacked semiconductor device shown in FIG. 12A. One regular interchip interconnect among four regular interchip interconnects is here taken up for explanation.

FIG. 13 shows one example of the redundancy remedy circuit configuration of chip C and chip D shown in FIG. 12A.

As shown in FIG. 13, regular interchip interconnect 112 between chip C and chip D is connected by way of tristate buffers 68 and 66 on chip C to regular interchip interconnect 113 between chip B and chip C, and further, is connected by way of tristate buffers 70 and 72 on chip D to regular interchip interconnect 114 between chip D and chip E.

Reserve interchip interconnect 122 between chip C and chip D is connected by way of tristate buffers 69 and 67 on chip C to reserve interchip interconnect 123 between chip B and chip C, and further, is connected by way of tristate buffers 73 and 71 on chip D to regular interchip interconnect 124 between chip D and chip E.

On chip C, chip-C internal wiring 131 is provided for connecting the junction point of tristate buffers 68 and 66 to the junction point of tristate buffers 69 and 67. Chip-C internal wiring 131 is connected to circuit C.

For selecting a path with chip D, chip C includes, in addition to the above-described configuration: flip-flop circuit 79 for determining the test signals from chip D; tristate buffer 75 for enabling the selection of whether or not to send a test signal from test signal generation circuit (not shown) to chip D; and NOR circuit 83, which is a logic gate for preventing the flow of test signals to other circuits.

The output terminal of tristate buffer 75 and the clock input terminal of flip-flop circuit 79 are connected to the junction point of regular interchip interconnect 112 and tristate buffer 68. The output terminal of flip-flop circuit 79 is connected to the control signal input terminal of tristate buffer 69 and the first input terminal of NOR circuit 83. Control signal TE0 that differs from control signal TE1 of tristate buffer 75 is applied as input to the second input terminal of NOR circuit 83. The output terminal of NOR circuit 83 is connected to the control signal input terminal of tristate buffer 68.

As shown in FIG. 13, flip-flop circuit 78, tristate buffer 74, and NOR circuit 82 are provided on chip C for selecting a path with chip B. In addition, chip D includes flip-flop circuits 80 and 81, tristate buffers 76 and 77, and NOR circuits 84 and 85 for selecting a path with each of chip C and chip E.

Tristate buffers 66-77 enter enabled states when high-level control signals are received as input. Control signal TE0 is applied as input to tristate buffers 74 and 76, and control signal TE1 is applied as input to tristate buffers 75 and 77. Control signal TE1 is applied as input to NOR circuits 82 and 84, and control signal TE0 is applied as input to NOR circuits 83 and 85.

Explanation next regards the operations for testing of interchip interconnects and redundancy remedy switching that are carried out at the time of start-up of the stacked semiconductor device of the present working example with reference to the example of circuit configuration shown in FIG. 13. In this case, regular interchip interconnect 12 is assumed to be electrically defective.

The outputs for flip-flop circuits 79 and 80 of the test determination circuit for path selection between chip C and chip D are set to the initial value “1”, whereby the path of reserve interchip interconnect 122 is selected rather than that of regular interchip interconnect 112.

Making control signal TE0 low level and control signal TE1 high level enables tristate buffer 75. A test signal from chip C is sent by way of tristate buffer 75 to regular interchip interconnect 112. If regular interchip interconnect 112 is normal, a test signal that passes through regular interchip interconnect 112 is received as input at the clock input terminal of flip-flop circuit 80. The output of flip-flop circuit 80 is set to “1” in its initial state, but upon reception of the toggle waveform that is the test signal, the output transitions to the input value “0”, whereby tristate buffer 71 is no longer enabled and the connection between circuit D and reserve interchip interconnect 122 is cut.

In the present working example, however, regular interchip interconnect 112 is defective, whereby the toggle waveform is not received at flip-flop circuit 80 and the output “1” of flip-flop circuit 80 is maintained. As a result, tristate buffer 71 remains unchanged in an enabled state and the connected state between circuit D and reserve interchip interconnect 122 is maintained.

Control signal TE0 is next made high level and control signal TE1 is made low level, whereby tristate buffer 76 is enabled. A test signal from chip D is sent by way of tristate buffer 76 to regular interchip interconnect 112. Flip-flop circuit 79 of the determination circuit of chip C determines whether the test signal is conveyed or not. If regular interchip interconnect 112 is normal, the toggle waveform that is the test signal is applied as input to the clock input terminal of flip-flop circuit 79. Flip-flop circuit 79, upon receiving the toggle waveform that is the test signal, causes its output to transition from the initial value “1” to input value “0”, whereby tristate buffer 69 is no longer enabled and the connection between circuit C and reserve interchip interconnect 122 is cut.

In the present working example, however, regular interchip interconnect 112 is defective, and as a result, the toggle waveform is not applied to flip-flop circuit 79 and the output of flip-flop circuit 79 remains unchanged as “1”. Tristate buffer 69 therefore maintains an enabled state, and the connected state between circuit C and reserve interchip interconnect 122 is maintained.

Accordingly, a path is selected such that reserve interchip interconnect 122 is used without using regular interchip interconnect 112 between chip C and chip D.

In the semiconductor device of the present working example, determinations of defects and redundancy switching are carried out independently between each of the chips, and increase in the time required for the redundancy remedy can therefore be avoided regardless of the increase in the number of stacked chips. When a large amount of transient current flows within the device due to testing and path switching carried out simultaneously on all of the chips, the test starting times can be slightly shifted for each chip or for each interchip interconnect to reduce the current that flows simultaneously.

The present invention is not limited by the above-described working examples and is open to various modifications within the scope of the invention, and these modifications are of course included within the scope of the present invention.

1-17. (canceled)

18. A semiconductor device comprising:
a first interchip interconnect for electrically connecting a first semiconductor chip and a second semiconductor chip;
a second interchip interconnect for a reserve for said first interchip interconnect;
a test signal generation circuit provided on said first semiconductor chip for transmitting a test signal by way of said first interchip interconnect to said second semiconductor chip;
a determination circuit provided on said second semiconductor chip for supplying a first control signal upon receiving said test signal by way of said first interchip interconnect and for supplying a second control signal that is an inverted signal of said first control signal when said test signal is not received; and
a switching circuit provided on said second semiconductor chip for setting said first interchip interconnect as a path for electrically connecting said first semiconductor chip and said second semiconductor chip upon receiving as input said first control signal from said determination circuit and for setting said second interchip interconnect as said path upon receiving as input said second control signal.

19. The semiconductor device according to claim 18, wherein said test signal indicates transition from low level to high level, or from high level to low level in voltage.

20. The semiconductor device according to claim 18, wherein:
said determination circuit includes a flip-flop circuit; and
said flip-flop circuit, upon receiving said test signal at a clock input terminal, supplies said switching circuit with data input value as said first control signal.

21. The semiconductor device according to claim 19, wherein:
said determination circuit includes a flip-flop circuit; and
said flip-flop circuit, upon receiving said test signal at a clock input terminal, supplies said switching circuit with data input value as said first control signal.

22. The semiconductor device according to claim 18, wherein:
said determination circuit includes a shift register wherein a plurality of stages of flip-flop circuits are connected in a series; and
said shift register, upon reception at a clock input terminal of a number of said test signals that is greater than the number of said plurality of stages, supplies data input value of a first stage of said plurality of stages from an output terminal of a final stage to said switching circuit as said first control signal.

23. The semiconductor device according to claim 19, wherein:
said determination circuit includes a shift register wherein a plurality of stages of flip-flop circuits are connected in a series; and
said shift register, upon reception at a clock input terminal of a number of said test signals that is greater than the number of said plurality of stages, supplies data input value of a first stage of said plurality of stages from an output terminal of a final stage to said switching circuit as said first control signal.

24. The semiconductor device according to claim 18, wherein said switching circuit includes:
a first buffer circuit connected between an internal circuit of said second semiconductor chip and said first interchip interconnect for, upon input of said first control signal from said determination circuit, connecting said first interchip interconnect to said internal circuit; and
a second buffer circuit connected between said internal circuit and said second interchip interconnect for, upon input of said second control signal from said determination circuit, connecting said second interchip interconnect to said internal circuit.

25. The semiconductor device according to claim 19, wherein said switching circuit includes:
a first buffer circuit connected between an internal circuit of said second semiconductor chip and said first interchip interconnect for, upon input of said first control signal from said determination circuit, connecting said first interchip interconnect to said internal circuit; and
a second buffer circuit connected between said internal circuit and said second interchip interconnect for, upon input of said second control signal from said determination circuit, connecting said second interchip interconnect to said internal circuit.

26. The semiconductor device according to claim 20, wherein said switching circuit includes:
a first buffer circuit connected between an internal circuit of said second semiconductor chip and said first interchip interconnect for, upon input of said first control signal from said determination circuit, connecting said first interchip interconnect to said internal circuit; and
a second buffer circuit connected between said internal circuit and said second interchip interconnect for, upon input of said second control signal from said determination circuit, connecting said second interchip interconnect to said internal circuit.

27. The semiconductor device according to claim 22, wherein said switching circuit includes:
a first buffer circuit connected between an internal circuit of said second semiconductor chip and said first interchip interconnect for, upon input of said first control signal from said determination circuit, connecting said first interchip interconnect to said internal circuit; and
a second buffer circuit connected between said internal circuit and said second interchip interconnect for, upon input of said second control signal from said determination circuit, connecting said second interchip interconnect to said internal circuit.

28. The semiconductor device according to claim 20, wherein said flip-flop circuit maintains output of said first control signal or said second control signal to said switching circuit until initialization is carried out or until supply of power is halted.

29. The semiconductor device according to claim 22, wherein said flip-flop circuit maintains output of said first control signal or said second control signal to said switching circuit until initialization is carried out or until supply of power is halted.

30. The semiconductor device according to claim 18, wherein said test signal generation circuit causes transmission timing and transmission period of said test signal to correspond to input/output cycles of data that are exchanged between said first semiconductor chip and said second semiconductor chip.

31. The semiconductor device according to claim 18, wherein said semiconductor device includes three or more semiconductor chips, and said first semiconductor chip and said second semiconductor chip are two semiconductor chips included in said three or more semiconductor chips.

32. The semiconductor device according to claim 18, wherein said semiconductor device is of a configuration in which said first semiconductor chip and said second semiconductor chip are stacked.

33. The semiconductor device according to claim 32, wherein said first interchip interconnect and said second interchip interconnect are through-type interconnects that are formed to pass through said first semiconductor chip or said second semiconductor chip.

34. The semiconductor device according to claim 18, wherein said test signal generation circuit transmits said test signal to said second semiconductor chip at the time of start-up of said first semiconductor chip and said second semiconductor chip.

35. The semiconductor device according to claim 18, wherein said test signal generation circuit transmits said test signal to said second semiconductor chip during operation of an internal circuit of said first semiconductor chip and said second semiconductor chip.

36. A semiconductor chip having an interchip interconnect for connection to another semiconductor chip or to two or more other semiconductor chips, said semiconductor chip comprising a circuit for generating a test signal indicating transition from low level to high level or from high level to low level in voltage and transmitting said test signal to said interchip interconnect to examine a connection state of said interchip interconnect.

37. A semiconductor chip having interchip interconnects for connection to another semiconductor chip or to two or more other semiconductor chips, said semiconductor chip comprising:
a determination circuit for supplying a first control signal upon reception of a test signal for examining a connection state of said interchip interconnects from a first interchip interconnect and for supplying a second control signal that is an inverted signal of said first control signal when said test signal is not received; and
a switching circuit for setting said first interchip interconnect upon input of said first control signal from said determination circuit and for switching to a second interchip interconnect in place of said first interchip interconnect upon input of said second control signal.

38. A semiconductor chip according to claim 36, comprising:
a determination circuit for supplying a first control signal upon reception of said test signal from a first interchip interconnect and for supplying a second control signal that is an inverted signal of said first control signal when said test signal is not received; and
a switching circuit for setting said first interchip interconnect upon input of said first control signal from said determination circuit, and switching to a second interchip interconnect in place of said first interchip interconnect upon input of said second control signal.

39. A interchip interconnect test method that is a method for testing a first interchip interconnect for electrically connecting a first semiconductor chip and second semiconductor chip, said interchip interconnect test method comprising the steps wherein:
a test signal generation circuit provided on said first semiconductor chip transmits a test signal by way of said first interchip interconnect matched to input/output cycles of data signals exchanged by said first semiconductor chip and said second semiconductor chip; and
a determination circuit provided on said second semiconductor chip supplies a first control signal when said test signal is received by way of said first interchip interconnect and supplies a second control signal that is an inverted signal of said first control signal when said test signal is not received.

40. An interchip interconnect switching method that is a method for switching between a first interchip interconnect for electrically connecting a first semiconductor chip and a second semiconductor chip and a second interchip interconnect provided as a reserve for said first interchip interconnect, said interchip interconnect switching method comprising the steps wherein:
a test signal generation circuit provided on said first semiconductor chip transmits a test signal by way of said first interchip interconnect matched to input/output cycles of data signals exchanged by said first semiconductor chip and said second semiconductor chip;
a determination circuit provided on said second semiconductor chip supplies a first control signal when said test signal is received by way of said first interchip interconnect and supplies a second control signal that is an inverted signal of said first control signal when said test signal is not received;
a switching circuit provided on said second semiconductor chip sets said first interchip interconnect as a path for electrically connecting said first semiconductor chip and said second semiconductor chip when said first control signal is received as input from said determination circuit;
said switching circuit sets said second interchip interconnect as said path when said second control signal is received as input; and
said interchip interconnect setting is carried out with each reception of said first or second control signal from said determination circuit.
